(19) United States
(12) Patent Application Publication
(10) Pub. No.: US 2026/0169070 A1
(43) Pub. Date: Jun. 18, 2026

(54) MONITORING SOLUTIONS FOR ELECTRICAL SYSTEMS

(71) Applicant: ABB Schweiz AG, Baden (CH)

(72) Inventors: Yannick Maret, Aargau (CH); Matija Varga, Zurich (CH); Artur Zawadzki, Krakow (PL); Mateusz Jablonski, Krakow (PL); David Salido Monzu, Zurich (CH); Andreas Port, Opfikon (CH)

(21) Appl. No.: 19/387,805

(22) Filed: Nov. 13, 2025

(30) Foreign Application Priority Data
Dec. 16, 2024 (EP) 24220091.3

(51) Int. Cl. G01R 31/327; G01R 19/165; G01R 23/16; G01R 31/42

(52) U.S. Cl. CPC G01R 31/3277; G01R 19/16547; G01R 23/16; G01R 31/42

(57) ABSTRACT

A method for probing a circuit breaker electrically connected to an electric line is described. The method comprises injecting one or more first signals at a first point of said electric line, wherein said one or more first signals have frequency content at least partially included in a predefined frequency range. The method further comprises detecting one or more second signals at a second point of said electric line, wherein said one or more second signals are detected with a detection frequency band calculated based on said frequency range. The method further comprises calculating a frequency response function indicative of a frequency response of said electric line in said frequency range based on the detected one or more second signals.

### CROSS REFERENCE TO RELATED APPLICATIONS

The present application claims priority to European Patent Application No. 24220091.3 filed on Dec. 16, 2024, and titled “IMPROVED MONITORING SOLUTIONS FOR ELECTRICAL SYSTEMS”, which is hereby incorporated by reference in its entirety.

### TECHNICAL FIELD

The present disclosure relates to the field of electrical systems, in some embodiments, operating at low-voltage levels. More particularly, the present disclosure relates to an improved method for probing a circuit breaker in an electrical system. The probing method, according to the present disclosure, can be advantageously adopted in monitoring methods for determining an operating state of a circuit breaker. According to a further aspect, the present disclosure relates to a monitoring device for determining an operating state of a circuit breaker, which is configured to carry out the probing method of the present disclosure.

### BACKGROUND

Generally, low-voltage electrical systems, such as electrical installations at residential, commercial business or industrial sites, include a number of circuit breakers configured to carry out protection functionalities of specific electrical lines or grid sections.

Normally, circuit breakers of a low-voltage electrical system have standardized dimensions and are mounted on installation rails arranged in suitable electrical panels. Typically, these devices can take a closed state, at which an electrical current is allowed to flow along a corresponding electrical line, and a tripped state or open state, at which an electrical current flowing along said electrical line is interrupted.

Nowadays, several applications, for example, most recent smart-home systems or electrical installations including distribution and sub-distribution panels at different physical locations, require that the operating conditions of circuit breakers be monitored in order to ensure a fast intervention in case of a fault.

Most traditional solutions designed for the purpose of monitoring the operating state of a circuit breaker foresee that a side accessory is mechanically coupled to the circuit breaker in order to switch together with this latter and signal the operating state of the circuit breaker through a suitable I/O interface. Unfortunately, these solutions may be difficult to employ (for example, during retrofitting interventions) as additional spaces in proximity of circuit breakers have to be foreseen on the installation rails to allow the above-mentioned accessory devices to be mounted.

Patent document EP4119959A1 discloses a device for monitoring the operating state of a circuit breaker in a low-voltage electrical system.

The monitoring device disclosed in the above-mentioned patent document is configured to probe the circuit breaker by injecting and detecting AC signals through the electric line, on which the circuit breaker is installed, and determine the operating status of the circuit breaker based on the detection signals acquired through the above-mentioned probing activity.

The monitoring device comprises a signal transceiver comprising a transmitter arrangement, which is operatively coupled to an electric line at a first point, and receiver arrangement, which is operatively coupled to said electric line, at a second point.

The transmitter arrangement is configured to generate a first signal and inject this latter into the electric line at the above-mentioned first point. The receiver arrangement is configured to receive a second signal from the electric line at the second point in response to the injection of the above-mentioned first signal by the transmitter arrangement.

The disclosed monitoring device further comprises a signal processor, which is operatively coupled to the signal transceiver and is configured to determine the state of the circuit breaker by suitably processing the second signal received by the receiver arrangement of the signal transceiver.

A remarkable advantage of the monitoring devices of this type consists in that they are characterized by a high flexibility in installation. In fact, they do not need to be mechanically coupled to a circuit breaker and, therefore, they do not have to be mounted on the installation rails in the immediate vicinity of a circuit breaker.

These monitoring devices can thus be installed in operating positions suitably selected depending on the physical configuration of the electrical panel, for example between the installation rails or on the top or bottom of the installed circuit breakers.

Notwithstanding the above, these monitoring devices have still some aspects to improve.

It has been seen that their performances are highly influenced by the electric loads electrically connected to the electric line associated to the monitored circuit breaker and the cabling characteristics and topology of said electric line.

Depending on the nature and physical layout of the electric loads and/or the cabling characteristics and topology of the electric line, the signals injected at a specific frequency into the electric line by the monitoring devices may thus be subject to relevant frequency-dependent attenuation, which can make the determination process of the operating state of the circuit breaker very uncertain or even impossible.

In the market, it is quite felt the need for innovative solutions able to overcome or mitigate the above-mentioned technical issues of these recent solutions of the state of the art.

### BRIEF DESCRIPTION

The present disclosure intends to respond to this need by providing a method for probing a circuit breaker. The objects of the present disclosure are achieved by the subject-matter of the independent claim. Further exemplary embodiments are evident from the dependent claims and the following description. The embodiments and features, if any, described in this specification that do not fall under the scope of the independent claim are to be interpreted as examples useful for understanding various embodiments of the present disclosure.

According to an aspect of the present disclosure, a method for probing a circuit breaker electrically connected to an electric line is provided. The method comprises injecting one or more first signals at a first point of the electric line, wherein the one or more first signals have frequency content at least partially included in a predefined frequency range; detecting one or more second signals at a second point of the electric line, wherein the one or more second signals are detected with a detection frequency band calculated based on the frequency range; and calculating a frequency response function indicative of a frequency response of the electric line in the frequency range based on the detected one or more second signals.

According to another aspect of the present disclosure, a device for monitoring an operating state of a circuit breaker electrically connected to an electric line is provided. The device is configured to: inject one or more first signals at a first point of the electric line, wherein the one or more first signals have frequency content at least partially included in a predefined frequency range; detect one or more second signals at a second point of the electric line, wherein the one or more second signals are detected with a detection frequency band calculated based on the frequency range; and calculate a frequency response function indicative of a frequency response of the electric line in the frequency range based on the detected one or more second signals.

According to another aspect of the present disclosure, a low-voltage electrical system is provided. The low-voltage electrical system comprises an electric line, a circuit breaker electrically connected to the electric line, and a device configured to monitor an operating state of the circuit breaker. The device is configured to: inject one or more first signals at a first point of the electric line, wherein the one or more first signals have frequency content at least partially included in a predefined frequency range; detect one or more second signals at a second point of the electric line, wherein the one or more second signals are detected with a detection frequency band calculated based on the frequency range; and calculate a frequency response function indicative of a frequency response of the electric line in the frequency range based on the detected one or more second signals.

### BRIEF DESCRIPTION OF DRAWINGS

The subject matter of the present disclosure will be explained in more detail in the following text with reference to exemplary embodiments which are illustrated in the attached drawings.

FIG. 1 is a schematic view showing an electrical system including a circuit breaker and a monitoring device operatively associated to said circuit breaker and capable of carrying out the probing method according to an embodiment of the present disclosure.

FIGS. 2-4 are schematic diagrams showing the operating activities of the probing method according to an embodiment of the present disclosure.

FIGS. 5-6 are schematic diagrams showing the operating activities of a monitoring method including the probing method according to an embodiment of the present disclosure.

The reference symbols used in the drawings, and their meanings, are listed in summary form in the list of reference symbols. In principle, identical parts are provided with the same reference symbols in the figures.

### DETAILED DESCRIPTION

Reference will now be made in detail to the various embodiments, one or more examples of which are illustrated in each figure. Each example is provided by way of explanation and is not meant as a limitation. For example, features illustrated or described as part of one embodiment can be used on or in conjunction with any other embodiment to yield yet a further embodiment. It is intended that the present disclosure includes such modifications and variations.

Within the following description of the drawings, the same reference numbers refer to the same or to similar components. In some instances, the same or similar components may be assigned a different reference number, for example, due to a different configuration within the electronic circuit. Generally, only the differences with respect to the individual embodiments are described. Unless specified otherwise, the description of a part or aspect in one embodiment applies to a corresponding part or aspect in another embodiment as well.

With reference to the above-mentioned figures, the present disclosure concerns improved monitoring solutions for electrical systems (for example, electric grids, electric switchgear systems, electric switchboards, and the like), which, in some embodiments, operate at low-voltage levels, in other words, at voltage levels lower than 1.5 kV AC and 2.0 kV DC. More particularly, the present disclosure relates to an improved probing method 100 of a circuit breaker in an electrical system.

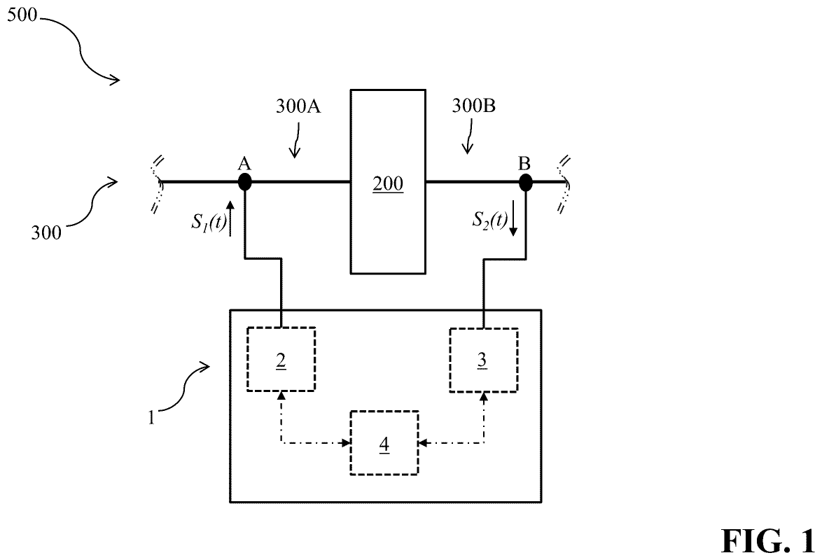

FIG. 1 shows an exemplary electrical system 500 operating at low-voltage levels.

The electrical system 500 comprises a low-voltage electric line 300, which is intended to connect electrically two different grid sections, each of which may include one or more electric power sources and/or one or more electric loads.

The electric line 300 can comprise one or more phase conductors and, possibly, also a neutral conductor. As an example, the electric line 300 may be arranged according to a 1P+N configuration, a 3P configuration, a 3P+N configuration, or a 2P+N configuration.

The electrical system 500 comprises a circuit breaker 200 operatively coupled to the electric line 300. Namely, the circuit breaker 200 is electrically connected between a first line section 300A and a second line section 300B of the electric line 300.

In general, the circuit breaker 200 may be of any type adapted for the employment in an electrical system operating at AC or DC low-voltage levels. For example, it may be a MCB (Miniature Circuit Breaker), a RCCB (Residual Current Circuit Breaker) device, or a RCBO (Residual Current circuit Breaker with Overcurrent protection) device, or a RCM (Residual Current Monitor) device, or the like.

In operation, the circuit breaker 200 can take a closed state, at which it allows the flow of a current along the electric line 300, or can take an open or tripped state, at which it prevents a current to flow along the electric line 300.

A transition from a closed state to an open or tripped state forms an opening maneuver or a tripping maneuver of the circuit breaker 200 while a transition from an open or tripped state to a closed state forms a closing maneuver of the circuit breaker.

Depending on how the electrical system 500 is configured, the energy flow along the electric line 300 can be directed from the first line section 300A to the second line section 300B, or vice-versa. For the circuit breaker 200, each of the line sections 300A, 300B may thus be considered as an input power supply line or an output power supply line.

In general, the electric line 300 and the circuit breaker 200 of the electrical system 500 may be realized according to solutions of known type. In the following, these elements will thus not be described in more details for the sake of brevity.

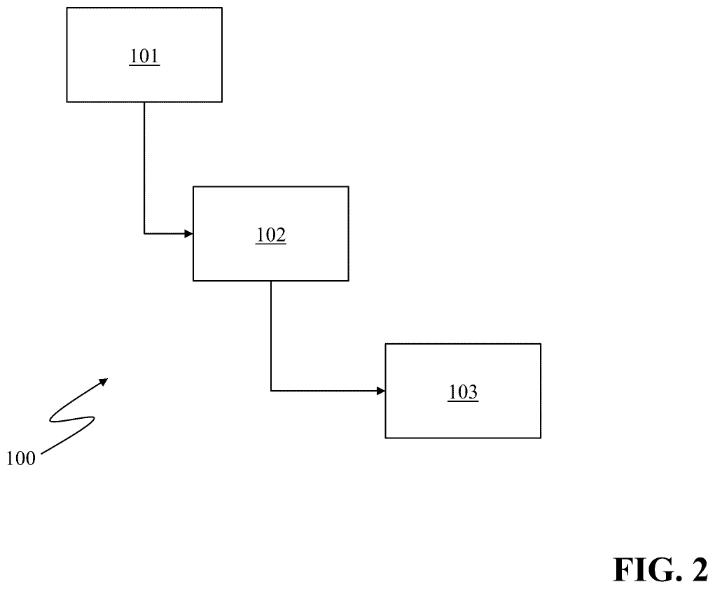

Referring now to FIG. 2, the probing method 100, according to an embodiment of the present disclosure, is now described in detail.

According to the present disclosure, the probing method 100 comprises an activity 101, in which one or more first signals S₁(t) are generated and injected at a first point A (injection point) of the electric line 300.

In the embodiment shown in FIG. 1, the first point A, at which the one or more first signals S₁(t) are injected, is located at the first line section 300A of the electric line. In principle, however, it can be positioned anywhere along the electric line, for example at the second line section 300B of the electric line.

In some embodiments, the one or more first signals S₁(t) are current or voltage signals having high frequency content, for example in the order of MHz.

In some embodiments, the one or more first signals S₁(t) are AC signals.

The one or more first signals S₁(t), which are injected into the electric line 300, have a frequency content at least partially included in a predefined frequency range F spanning, for example, between 1 MHz to 10 MHz. As an example, the one or more first signals S₁(t) take at least some different frequency values included in the predefined frequency range F, or have an instantaneous frequency value varying continuously in the predefined frequency range F, or have a frequency spectrum spanning across the predefined frequency range F.

According to the present disclosure, the probing method 100 comprises a second activity 102, in which one or more second signals S₂(t) are detected at a second point B (detection point) of the electric line 300.

In the embodiment shown in FIG. 1, the second point B, at which the one or more second signals S₂(t) are detected, is located at the second line section 300B of the electric line. In principle, however, it can be positioned anywhere along the electric line, for example at the first line section 300A of the electric line.

In some embodiments, the one or more second signals S₂(t) are AC signals.

In some embodiments, the one or more second signals S₂(t) are current or voltage signals having high frequency content, for example in the order of MHz.

The one or more second signals S₂(t) are detected with a detection frequency band DFB, which is conveniently calculated based on the frequency range F including the frequency content of the one or more first signals S₁(t) injected at the first point A of the electric line.

According to the present disclosure, the probing method 100 comprises a third activity 103, in which a frequency response function G(f) of the electric line 300 is calculated.

The frequency response function G(f) is indicative of the frequency response of the electric line 300 to the injection of the one or more first signals S₁(t) injected at the first point A of said electric line. In practice, the frequency response function G(f) describes the behavior (in frequency) of the communication channel between the points A, B of the electric line.

The frequency response function G(f) of the electric line 300 is calculated in the predefined frequency range F including the frequency content of the one or more first signals S₁(t) and it is reconstructed based on the one or more second signals S₂(t) detected at the second point B of the second line section 300B.

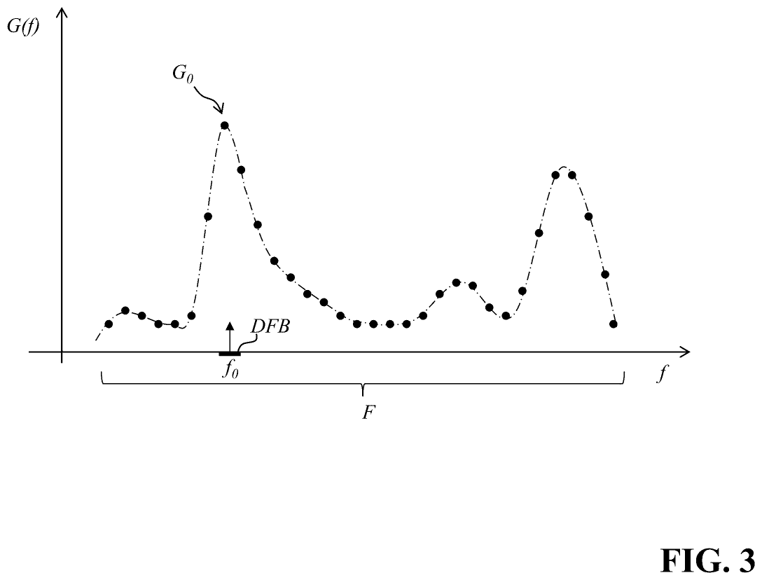

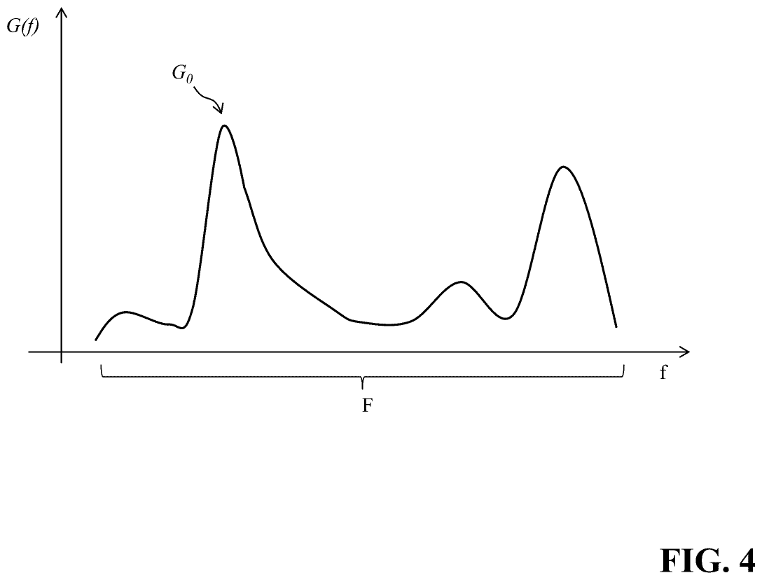

FIGS. 3-4 show examples of frequency response functions G(f) of the electric line as reconstructed according to the probing method 100 of the present disclosure.

As it is possible to notice, the magnitude (for example, measured in Volt) of the frequency response function G(f) shows large variations across frequency in the predefined frequency range F including the frequency content of the one or more first signals injected at the first point A of the electric line 300.

This behavior is basically due to the circumstance that the signal attenuation, to which the injected one or more first signals S₁(t) are subject, varies remarkably with frequency depending on the nature and layout of the electric loads electrically connected to the electric line and the cabling characteristics and topology of the electric line.

Notwithstanding the above, the reconstructed frequency response function G(f) of the electric line provides information on the signal attenuation along this latter. For example, it allows identifying certain frequencies, at which the above-mentioned signal attenuation is relatively low. As it will be better explained in the following, this allows collecting detection data that can be suitably processed to determine the state of the circuit breaker 200 with an elevated level of reliability.

According to some embodiments of the present disclosure, the first activity 101 of the probing method 100 includes injecting a plurality of first sinusoidal signals S₁(t) at the first point A of the electric line 300.

The one or more first sinusoidal signals S₁(t) are distinct one from another and have each a predefined frequency included in the predefined frequency range F.

In some embodiments, each first sinusoidal signal S₁(t) is injected for a predefined injection time interval.

In some embodiments, the first sinusoidal signals S₁(t) are injected in sequence one after the other until the predefined frequency range F is covered with a desired frequency resolution value.

According to these embodiments of the present disclosure, the second activity 102 of the probing method 100 includes detecting a plurality of second signals S₂(t) at the second coupling point B of the electric line 300.

Each second signal S₂(t) is detected in response to the injection of a corresponding first sinusoidal signal S₁(t) at the first point A of the electric line 300.

In some embodiments, each second signal S₂(t) is detected for a predefined detection time interval, which may correspond to the predefined injection time interval of the corresponding injected first sinusoidal signal S₁(t).

In general, the one or more detected second signals S₂(t) are not sinusoidal signals as they include spurious components that need to be filtered.

For this reason, according to the present disclosure, each second signal S₂(t) is detected with a detection frequency band DFB including the frequency value of a corresponding injected first sinusoidal signal S₁(t). In this way, possible signal components at frequencies different from the frequency value taken by the injected first sinusoidal signal S₁(t) can be filtered (FIG. 3).

In some embodiments, the detection frequency band DFB is centered on the frequency value of a corresponding injected first sinusoidal signal S₁(t).

The width of the detection frequency band DFB basically depends on the bandwidth of the injected first sinusoidal signals S₁(t). In general (FIG. 3), the detection frequency band DFB for detecting a generic second signal S₂(t) is relatively narrow compared to the extension of the predefined frequency range F. For example, the detection frequency band DFB for detecting a second signal S₂(t) having a certain frequency f₀ may be of DFB=0.2 MHz, if the predefined frequency range F spans between 1 MHz and 10 MHz with a frequency resolution value of 0.25 MHz.

According to the above-mentioned embodiments of the present disclosure, the third activity 103 of the probing method 100 includes calculating, for each detected second signal S₂(t), an average power value P over time of said second signal.

In some embodiments, the average power value P of each second signal S₂(t) is calculated over the above-mentioned detection time interval, during which said second signal is detected.

The calculation of the average power value P of each second signal S₂(t) can be conveniently carried out through well-known signal processing techniques.

As an example, the average power value P₀ of a second signal S₂(t) detected in response to the injection of a first sinusoidal signal S₁(t) having a certain frequency f₀ can be calculated according to the following relationship:

$${{P}_{0}}^{=} \frac{1}{T} {\int }_{0}^{T} \vert {{S}_{2 B} ( t )}^{2} \vert dt$$

where T is the detection time interval of the detected second signal S₂(t) and S_{2B}(t) is the detected second signal S₂(t) filtered in a detection frequency band DFB including the frequency f₀ of the injected first sinusoidal signal S₁(t).

According to the above-mentioned embodiments of the present disclosure, the third activity 103 of the probing method 100 further includes calculating the frequency response function G(f) of the electric line 300 based on the average power values P₀ calculated for the detected second signals S₂(t).

The calculation of the frequency response function G(f) can be also carried out through well-known signal processing techniques.

As shown in FIG. 3, the frequency response function G(f) of the electric line 300 can be calculated as a succession of magnitude values G, each of which is calculated based on the average power values P calculated for a corresponding detected second signal S₂(t).

As an example, for a certain second signal S₂(t) detected in response to the injection of a first sinusoidal signal S₁(t) having a certain frequency f₀, a magnitude value G₀ of the frequency response function G(f) may be calculated based on the following relationship:

$${G}_{0} = \sqrt{{P}_{0}}$$

where P₀ is the average power value calculated for the detected second signal S₂(t) as illustrated above.

The frequency response function G(f) of the electric line 300 can thus be reconstructed by calculating a succession of magnitude values corresponding to the different frequencies of the injected first sinusoidal signals S₁(t).

According to further embodiments of the present disclosure, the first activity 101 of the probing method 100 includes injecting (at the first point A of the electric line) a first signal S₁(t) having a frequency value continuously varying in time (with a given rate of change that may be constant or variable in time) within the predefined frequency range F.

As an example, the first signal S₁(t) can be a frequency modulated signal (for example, a chirp-up signal) having an instantaneous frequency increasing (for example, linearly) in time and having frequency values within the predefined frequency range F.

According to these further embodiments of the present disclosure, the second activity 102 of the probing method 100 includes detecting (at the second point B of the electric line) a second signal S₂(t) with a detection frequency band varying in time so as to include the instantaneous frequency value taken by a corresponding injected first signal S₁(t). In this way, signal components at frequencies different from the instantaneous frequency value taken by a corresponding injected first signal S₁(t) can be filtered.

In some embodiments, the detection frequency band is centered on the instantaneous frequency value taken by a corresponding injected first signal S₁(t).

Advantageously, the detection frequency band of the second signal S₂(t) varies in time according to the rate of change of the frequency of the injected first signal S₁(t). The instantaneous power value P(τ) of the second signal S₂(t) detected in response to the injection of the first signal S₁(t) can be calculated over a moving time window [τ−Δτ, τ+Δτ] according to the following relationship:

$$P ( τ ) = \frac{1}{2 Δ τ} {\int }_{τ - Δ τ}^{τ + Δ τ} \vert {{S}_{2} ( t )}^{2} \vert d t .$$

According to these embodiments of the present disclosure, the frequency response function G(f) of the electric line 300 can be directly calculated based on the calculated power P(τ). In fact, this latter is indicative of the magnitude of the frequency response function G(f) as it is the result of a time-to-frequency mapping applied to P(τ), enabled by the corresponding injected first signal S₁(t) having a known frequency continuously variable in time.

The calculation of the frequency response function G(f) can be carried out through well-known signal processing techniques.

As an example, the frequency response function G(f) of the electric line 300 can be calculated according to the following relationship:

$$G ( f ) = P ( k ( f ) )$$

where P(τ) is the computed instantaneous power of the detected second signal S₂(t) and k(f) is a function defining the frequency variation of the injected first signal S₁(t) with time. The function k(f) thus maps the time axis into frequency to reconstruct the frequency response function. The mapping function k(f) is linear in case the frequency value of the injected first signal S₁(t) varies linearly as explained above by way of example.

FIG. 4 shows an example of frequency response function G(f) of the electric line 300 calculated according to these further embodiments of the present disclosure. As it is possible to notice, the frequency response function G(f) can be a continuous function having a frequency domain corresponding to the predefined frequency range F.

According to further embodiments of the present disclosure, the first activity 101 of the probing method 100 includes injecting (at the first point A of the electric line) a first signal S₁(t) having a frequency spectrum, which extends across the predefined frequency range F.

As an example, the first signal S₁(t) can be shaped as a normalized sinc(t) function and expressed as:

$${S}_{1} ( t ) = \frac{sin π t}{π t}$$

in such a way to have a frequency spectrum substantially shaped as a rect(f) function, which has a frequency domain covering the predefined frequency range F.

According to these further embodiments of the present disclosure, the second activity 102 of the probing method 100 includes detecting (at the second point B of the electric line) a second signal S₂(t) with a detection frequency band having a width corresponding to the predefined frequency range F in such a way to filter signal components at frequencies not included in the predefined frequency range F.

According to these further embodiments of the present disclosure, the frequency response function G(f) of the electric line 300 is calculated by calculating the frequency spectrum of the detected second signal S₂(t).

The frequency spectrum of the detected second signal S₂(t) can be calculated through well-known signal processing techniques, for example FFT processing techniques.

The frequency spectrum of the detected second signal S₂(t) directly represents the frequency response function G(f) of the electric line to the injection of the first signal S₁(t).

Referring again to FIG. 4, the frequency response function G(f) of the electric line 300 calculated according to these embodiments of the present disclosure can also be a continuous function having a frequency domain corresponding to the predefined frequency range F.

The probing method 100 of the present disclosure can be advantageously employed in methods for monitoring the state of the circuit breaker 200 to collect information indicative of the operating state of this latter.

The calculation of the frequency response function G(f) of the electric line 300 in response to the injection of the one or more first signals S₁(t) allows identifying specific frequencies or frequency bands of the predefined frequency range F, at which the calculated frequency response functions G(f) indicate that a relatively low signal attenuation is introduced.

As a consequence, the behavior of the circuit breaker 200 can be monitored in a robust and reliable manner, substantially independent from the physical layout and characteristics of the electric loads electrically connected to the electric line 300 and from the cabling characteristics and topology of the electric line.

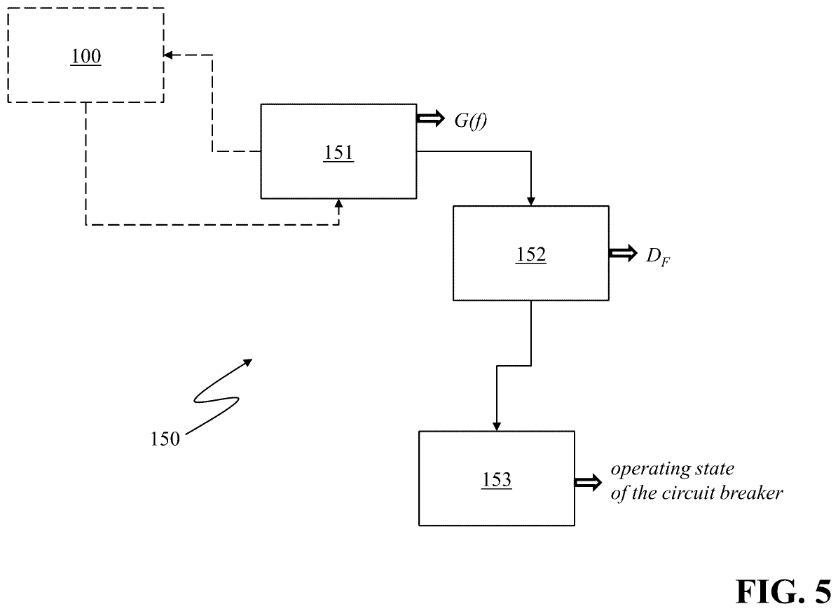

FIG. 5 shows an exemplary embodiment of a method 150 for monitoring the operating state of a circuit breaker 200.

In some embodiments, the monitoring method 150 comprises an activity 151 of repeating cyclically the probing method 100 of the present disclosure to calculate the frequency response function G(f) of the electric line 300 at subsequent iteration cycles of the probing method.

In some embodiments, the monitoring method 150 comprises an activity 152 of processing the calculated frequency response functions G(f) to obtain detection data D_{F} indicative of a behavior of the circuit breaker 200 at subsequent iteration cycles of the probing method.

In some embodiments, the detection data D_{F} comprises a collection of magnitude values at subsequent time instants, each of which represents the time instant in which a repetition cycle of the probing method is completed, and a corresponding frequency response functions G(f) is calculated.

These magnitude values can be conveniently selected for specific frequencies or frequency bands of the predefined frequency range F, at which the calculated frequency response functions G(f) show that a relatively low signal attenuation is introduced.

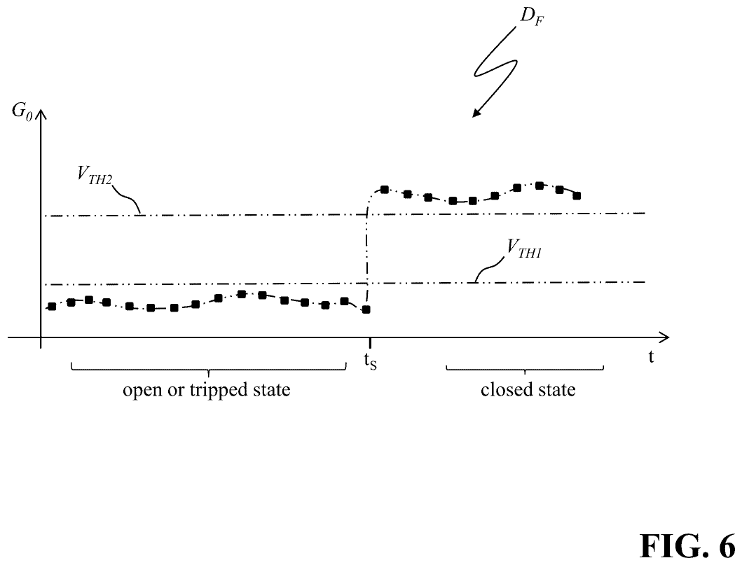

As an example, referring to FIG. 6, the detection data D_{F} may comprise a collection of magnitude values G₀, each of which is selected at a frequency at which the corresponding calculated frequency response function G(f) takes a maximum value.

As a further example, the detection data D_{F} may comprise a collection of magnitude values, each of which is computed as the average value of the frequency response function G(f) over a suitable frequency range.

The detection data D_{F} are indicative of the behavior of the circuit breaker 200 as the frequency response function G(f) of the electric line 300 at a given instant in time is strongly influenced by the operating state of the circuit breaker at said time instant.

As they are selected for frequencies at which the possible influence of electric loads electrically connected to the electric line and of the cabling characteristics and topology is reduced, the detection data D_{F} can represent in a robust manner the behavior of the circuit breaker 200 at subsequent instants in time.

The monitoring method 150 thus comprises an activity 153 of processing the detection data D_{F} to determine an operating state of a circuit breaker.

According to possible variants of the monitoring method, the detection data D_{F} are compared with one or more threshold values V_{TH1}, V_{TH2} to determine the operating state of the circuit breaker 200. Based on the result of such a comparison, the operating state of the circuit breaker is determined.

FIG. 6 shows an exemplary representation of detection data D_{F} obtained during the execution of a closing maneuver by the circuit breaker 200 (switching instant t_{S}).

As it is possible to notice, the collected magnitude values G₀ are relatively low before the switching instant t_{S} (circuit breaker in an open or tripped state) and are relatively high after the switching instant t_{S} (circuit breaker in a closed state).

By comparing the collected magnitude values G₀ with a lower threshold value V_{TH1} and with a higher threshold value V_{TH2}, it is possible to determine the operating state of the circuit breaker or understand whether the circuit breaker is carrying out a state transition.

According to other possible variants of the monitoring method, the detection data D_{F} are classified through a suitable classification method. To this aim, classification methods of known type can be adopted, for example classification methods employing support vector machine or k-nearest neighbor classifiers trained on reference data acquired in controlled conditions with known operating states of the circuit breakers.

Based on the result of such a classification, the operating state of the circuit breaker 200 is determined.

In a further aspect, the present disclosure relates to a device 1 for monitoring an operating state of a circuit breaker.

Referring back to FIG. 1, the monitoring device 1, in some embodiments, comprises a signal transceiver module 2, 3 and a signal processor module 4.

The signal transceiver module comprises a transmitter arrangement 2, which is operatively coupled (for example, in a capacitive or inductive manner) to the electric line 300 at the first point A, and a receiver arrangement 3, which is operatively coupled (for example, in a capacitive or inductive manner) to the electric line 300, at the second point B.

As mentioned above, the injection and detection points A, B may be located at a same line section 300A or 300B or be located at different line sections 300A, 300B as in the exemplary embodiment shown in FIG. 1.

The signal processor module 4 is operatively coupled with the signal transmitter arrangement 2 and the receiver arrangement 3 in such a way to exchange data signals and command signals with the latter.

In many aspects, the monitoring device 1 can be realized industrially according to solutions of known type, for example according to the solutions described in the above-mentioned patent document EP4119959A1.

However, the monitoring device 1 is equipped with signal processing means (which may be of digital and/or analog type) configured to carry out the probing method 100 of the present disclosure described above.

In some embodiments, the monitoring device 1 is equipped with signal processing means (which may be of digital and/or analog type) configured to carry out the monitoring method 150 described above.

In an electrical system 500, the monitoring device 1 can be mounted onboard or integrated in the circuit breaker 200 or constitute a separate unit from this latter. In this case, the monitoring device 1 does not need to be mounted in the immediate vicinity of the circuit breaker but it can be advantageously mounted in a suitable position within an electrical switchboard or panel.

It has been seen in practice how the monitoring solutions provided by the present disclosure provide relevant technical advantages over the state of the art.

The probing method, according to the present disclosure, allows collecting a comprehensive information about the frequency behavior of the communication channel between the signal injection point A and signal detection point B of the electric line.

This allows monitoring the operating state of a circuit breaker in a robust and reliable manner, substantially independent from the physical layout and nature of the electric loads electrically connected to the electric line and from the cabling characteristics and topology of the electric line.

The solution proposed by the present disclosure therefore allows a more efficient and safer determination of the operating state of a circuit breaker, thereby reducing the risk that faults or malfunctions of the electrical system remain unattended and favoring the execution of urgent interventions in case of faults.

The probing method, according to the present disclosure, requires relatively small computational resources to be carried out and is relatively easy and cheap to implement at industrial level.

Also, the described monitoring method and the monitoring device, according to the present disclosure, are relatively easy to implement at industrial level at competitive costs with currently available solutions of the state of the art.

While the present disclosure has been illustrated and described in detail in the drawings and foregoing description, such illustration and description are to be considered illustrative or exemplary and not restrictive; the present disclosure is not limited to the disclosed embodiments. Other variations to the disclosed embodiments can be understood and effected by those skilled in the art and practicing the present disclosure, from a study of the drawings, the disclosure, and the appended claims. In the claims, the word “comprising” does not exclude other elements or activities, and the indefinite article “a” or “an” does not exclude a plurality. A single processor or controller or other unit may fulfil the functions of several items recited in the claims. The mere fact that certain measures are recited in mutually different dependent claims does not indicate that a combination of these measures cannot be used to advantage. Any reference signs in the claims should not be construed as limiting the scope.

The disclosed systems and methods are not limited to the specific embodiments described herein. Rather, components of the systems or activities of the methods may be utilized independently and separately from other described components or activities.

This written description uses examples to disclose various embodiments, which include the best mode, to enable any person skilled in the art to practice those embodiments, including making and using any devices or systems and performing any incorporated methods. The patentable scope is defined by the claims and may include other examples that occur to those skilled in the art. Such other examples are intended to be within the scope of the claims if they have structural elements that do not differ from the literal language of the claims, or if they include equivalent structural elements with insubstantial differences form the literal language of the claims.

1. A method for probing a circuit breaker electrically connected to an electric line, the method comprising:
injecting one or more first signals at a first point of the electric line, wherein the one or more first signals have frequency content at least partially included in a predefined frequency range;
detecting one or more second signals at a second point of the electric line, wherein the one or more second signals are detected with a detection frequency band calculated based on the frequency range; and
calculating a frequency response function indicative of a frequency response of the electric line in the frequency range based on the detected one or more second signals.

2. The method according to claim 1, wherein injecting the one or more first signals comprises:
injecting a plurality of first sinusoidal signals, wherein each first sinusoidal signal has a predefined frequency value included in the predefined frequency range.

3. The method according to claim 2, wherein detecting the one or more second signals comprises:
detecting a plurality of second signals, wherein each second signal is detected with a detection frequency band including the frequency value of a corresponding injected first sinusoidal signal.

4. The method according to claim 3, wherein calculating the frequency response function of the electric line comprises:
calculating, for each detected second signal, an average power value over time of the second signal; and
calculating the frequency response function based on the average power values calculated for the detected second signals.

5. The method according to claim 1, wherein injecting the one or more first signals comprises:
injecting a first signal having an instantaneous frequency value continuously varying in time within the predefined frequency range.

6. The method according to claim 5, wherein detecting the one or more second signals comprises:
detecting a second signal with a detection frequency band varying in time so as to include the instantaneous frequency value taken by a corresponding injected first signal.

7. The method according to claim 6, wherein the frequency response function of the electric line is calculated based on the instantaneous power of the detected second signal.

8. The method according to claim 1, wherein injecting the one or more first signals comprises:
injecting a first signal having a frequency spectrum extending across the predefined frequency range.

9. The method according to claim 8, wherein detecting the one or more second signals comprises:
detecting a second signal with a detection frequency band having a width corresponding to the predefined frequency range.

10. The method according to claim 9, wherein the frequency response function of the electric line is determined by calculating the frequency spectrum of the detected second signal.

11. The method according to claim 1, wherein the method further comprises:
cyclically injecting the one or more first signals and detecting the one or more second signals to calculate the frequency response function of the electric line;
obtaining detection data indicative of a behavior of the circuit breaker at subsequent iteration cycles of the method; and
processing the detection data to determine an operating state of the circuit breaker.

12. The method according to claim 11, wherein processing the detection data comprises:
comparing the detection data with one or more of predefined threshold values; and
determining the operating state of the circuit breaker based on a result of the comparison.

13. The method according to claim 11, wherein processing the detection data comprises:
classifying the detection data through a classification; and
determining the operating state of the circuit breaker based on a result of the classification.

14. A device for monitoring an operating state of a circuit breaker electrically connected to an electric line, wherein the device is configured to:
inject one or more first signals at a first point of the electric line, wherein the one or more first signals have frequency content at least partially included in a predefined frequency range;
detect one or more second signals at a second point of the electric line, wherein the one or more second signals are detected with a detection frequency band calculated based on the frequency range; and
calculate a frequency response function indicative of a frequency response of the electric line in the frequency range based on the detected one or more second signals.

15. The device according to claim 14, wherein the device is further configured to:
cyclically injecting the one or more first signals and detecting the one or more second signals to calculate the frequency response function of the electric line;
obtain detection data indicative of a behavior of the circuit breaker at subsequent iteration cycles of the method; and
process the detection data to determine the operating state of the circuit breaker.

16. A low-voltage electrical system comprising:
an electric line;
a circuit breaker electrically connected to the electric line; and
a device configured to monitor an operating state of the circuit breaker, wherein the device is configured to:
inject one or more first signals at a first point of the electric line, wherein the one or more first signals have frequency content at least partially included in a predefined frequency range;
detect one or more second signals at a second point of the electric line, wherein the one or more second signals are detected with a detection frequency band calculated based on the frequency range; and
calculate a frequency response function indicative of a frequency response of the electric line in the frequency range based on the detected one or more second signals.

17. The low-voltage electrical system according to claim 16, wherein in the inject the one or more first signals, the device is further configured to:
inject a plurality of first sinusoidal signals, wherein each first sinusoidal signal has a predefined frequency value included in the predefined frequency range.

18. The low-voltage electrical system according to claim 16, wherein in the inject the one or more first signals, the device is further configured to:
inject a first signal having an instantaneous frequency value continuously varying in time within the predefined frequency range.

19. The low-voltage electrical system according to claim 16, wherein in the inject the one or more first signals, the device is further configured to:
inject a first signal having a frequency spectrum extending across the predefined frequency range.

20. The low-voltage electrical system according to claim 16, wherein the device is further configured to:
cyclically injecting the one or more first signals and detecting the one or more second signals to calculate the frequency response function of the electric line;
obtain detection data indicative of a behavior of the circuit breaker at subsequent iteration cycles of the method for probing the circuit breaker; and
process the detection data to determine the operating state of the circuit breaker.
